(19) United States
(12) Patent Application Publication
(10) Pub. No.: US 2008/0084678 A1
(43) Pub. Date: Apr. 10, 2008

(54) PRINTED CIRCUIT BOARD AND A METHOD FOR IMBEDDING A BATTERY IN A PRINTED CIRCUIT BOARD

(75) Inventors: Gary R. Burhance, Boynton Beach, FL (US); John C. Barron, Davie, FL (US); Jorge L. Garcia, Plantation, FL (US); David J. Meyer, Fort Lauderdale, FL (US)

Correspondence Address: MOTOROLA, INC., 1303 EAST ALGONQUIN ROAD, IL01/3RD, SCHAUMBURG, IL, 60196, US

(73) Assignee: MOTOROLA, INC., Schaumburg, IL (US)

(21) Appl. No.: 11/539,893

(22) Filed: Oct. 10, 2006

(51) Int. Cl. H05K 1/18

(52) U.S. Cl. 361/761

(57) ABSTRACT

A printed circuit board and a method for imbedding a battery in the printed circuit board are disclosed. The method includes connecting the battery to a first inner pad and a second inner pad on an inner core layer and forming a first battery contact between a first outer pad and the first inner pad. The method also includes electrically isolating the first battery contact and forming a second battery contact between a second outer pad and the second inner pad.

### FIELD OF THE INVENTION

The present invention relates in general to the field of printed circuit boards, and more specifically, to imbedding a battery in a printed circuit board.

### BACKGROUND

A printed circuit board (PCB) forms a major functional part of an electronic device. The PCB has conducting wires printed on a dielectric substrate. The conducting wires are printed in order to form a circuit pattern to interconnect various electronic components integrated with the PCB. The electronic components may be resistors, capacitors, diodes, transistors, Integrated Circuits (IC), and the like. In addition, the PCB requires a power source to power the electronic components integrated with the PCB.

There are existing schemes for providing the power source, such as a battery, for the electronic components integrated with the PCB in the electronic device. One such existing scheme includes providing a conventional battery package in the electronic device. In such a scheme, the conventional battery package is attached separately to the PCB and powers the electronic components integrated with the PCB. The connection between the conventional battery package and the electronic components is made by using contacts or soldering. The conventional battery package can be a conventional rechargeable battery or a battery printed on a flexible substrate such as paper.

However, a disadvantage of such a scheme is that the conventional battery package is provided separately from the PCB in the electronic device. Keeping the battery separate from the PCB may require special attachments for connection between the battery and the electronic device and having special attachments for connection is suboptimal. Accordingly, there is a need for a new PCB and a new method for imbedding a battery in a PCB.

### BRIEF DESCRIPTION OF THE FIGURES

The present invention is illustrated by way of example, and not limitation, in the accompanying figures, in which like references indicate similar elements, and in which:

FIG. 1 is a side view of a printed circuit board in accordance with an embodiment of the present invention.

FIG. 2 is a top view of the printed circuit board in accordance with an embodiment of the present invention.

FIG. 3 is a flowchart illustrating a method for imbedding a battery in a printed circuit board in accordance with an embodiment of the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Various embodiments of the present invention provide a printed circuit board and a method for imbedding a battery in a printed circuit board. The method includes connecting the battery to a first inner pad and a second inner pad, and forming a first battery contact for electrically connecting the first inner pad and a first outer pad. The method further includes electrically isolating the first battery contact, and forming a second battery contact for electrically connecting the second inner pad and a second outer pad.

Various embodiments of the present invention further provide a printed circuit board. The printed circuit board includes a plurality of core layers and a battery imbedded between two of the plurality of core layers. The printed circuit board further includes a first outer pad connected to a first battery contact pad, and a second outer pad connected to a second battery contact pad.

Before describing in detail the particular method for imbedding a battery in a printed circuit board in accordance with the present invention, it should be observed that the present invention resides primarily in combinations of method steps and apparatus components related to the method for imbedding the battery in the printed circuit board. Accordingly, the apparatus components and method steps have been represented where appropriate by conventional symbols in the drawings, showing only those specific details that are pertinent to understanding the present invention so as not to obscure the disclosure with details that will be readily apparent to those of ordinary skill in the art having the benefit of the description herein.

In this document, relational terms such as first and second and the like may be used solely to distinguish one entity or action from another entity or action without necessarily requiring or implying any actual such relationship or order between such entities or actions. The terms ‘comprises,’ ‘comprising,’ or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by ‘comprises . . . a’ does not, without more constraints, preclude the existence of additional identical elements in the process, method, article, or apparatus that comprises the element.

The term ‘another’, as used herein, is defined as at least a second or more. The terms ‘including’ and/or ‘having’, as used herein, are defined as comprising.

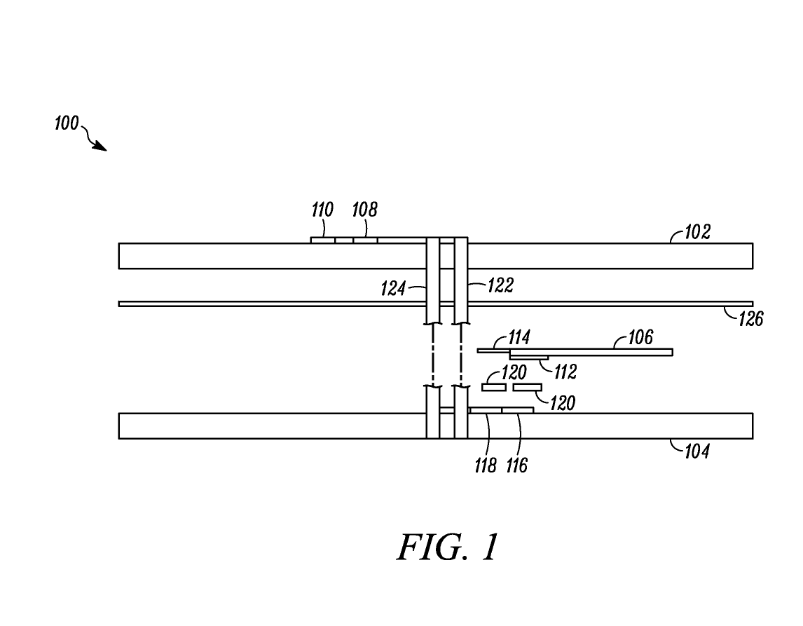

FIG. 1 is a side view of a printed circuit board (PCB) 100, in accordance with an embodiment of the present invention. The PCB 100 includes a plurality of core layers, such as an outer core layer 102 and an inner core layer 104. Even though only two core layers are shown in FIG. 1, an embodiment of the present invention may comprise more than two core layers. An example embodiment may comprise four core layers. In any case, each core layer functions to provide routing, power, or ground.

The PCB 100 also includes a battery 106, which is integrated on the inner core layer 104. As is known to one of ordinary skill in the art, the term battery is defined as a device that stores energy and makes it available in electrical form. As used herein, the term battery implies a single cell device generally known as an electrochemical battery. In an example battery of an embodiment of the present invention, the battery is a high temperature lithium cell capable of withstanding temperatures up to 200° C. In any case, the temperature that the battery is capable of withstanding is such that the battery can endure the temperatures produced during the PCB fabrication process.

The battery 106 includes a first battery contact pad 112 and a second battery contact pad 114. The outer core layer 102 of the PCB 100 includes a first outer pad 108 and a second outer pad 110. The first outer pad 108 and the second outer pad 110 provide outer connections for the first battery contact pad 112 and the second battery contact pad 114, respectively. Further, the inner core layer 104 includes a first inner pad 116 and a second inner pad 118. The first inner pad 116 is connected to the first battery contact pad 112, and the second inner pad 118 is connected to the second battery contact pad 114. In one embodiment, the first battery contact pad 112 is a printed anode for the battery 106 and the second battery contact pad 114 is a printed cathode for the battery 106.

The connections are made by using a conductive medium 120. Examples of the conductive medium 120 include conductive epoxy, solder, and the like. In an embodiment of the present invention, the conductive medium 120 is Kwik-Stik™ silver colloid manufactured by Structure Probe, Inc. In any case, the conductive medium 120 functions to carry electrical signals between the battery 106 and the inner core layer 104.

A first battery contact via 122 electrically connects the first outer pad 108 to the first inner pad 116. Similarly, a second battery contact via 124 electrically connects the second outer pad 110 to the second inner pad 118. In an embodiment of the present invention, the first outer pad 108, the second outer pad 110, the first inner pad 116, and the second inner pad 118 are metallic. As such, the first outer pad 108, the second outer pad 110, the first inner pad 116, and the second inner pad 118 are electrically conductive.

In one embodiment of the present invention, the outer pads 108, 110 comprise metallic copper material. In one embodiment of the present invention, the inner pads 116, 118 also comprise metallic copper material. In one embodiment of the present invention, the vias 122, 124 are made electrically conductive by copper plating. In any case, the vias 122, 124 may be mechanically drilled into the PCB 100.

The PCB 100 further includes one or more prepreg layers, provided between the plurality of core layers. A prepreg layer 126, as shown in FIG. 1, is present between the outer core layer 102 and the inner core layer 104. As is known to one of ordinary skill in the art, prepeg means a partially-cured epoxy resin embedded in fiberglass fabric used to bond multiple core layers of a PCB. In a specific embodiment of the present invention, the prepreg layer 126 comprises a flame resistant (FR) material termed FR4 with fiberglass style 7628 which means that the prepreg layer 126 has a weight of 200 g/m², a thickness of 0.190 mm, and 17/12 warp/weft.

In one embodiment, each of the plurality of core layers of the PCB 100 is coated with a black oxide coating prior to the battery 106 being imbedded in the PCB 100. In such an embodiment, a part of the black oxide coating is selectively removed to prevent any obstruction to the integration of the battery.

The PCB 100 further includes a plurality of electronic components (not shown) and a plurality of holes (not shown). The electronic components are connected to form a circuit. Examples of the electronic components integrated on the PCB include, but are not limited to, capacitors, resistors, diodes, transistors, and Integrated Circuits (ICs). The holes may be copper-plated and provide electrical connections for the plurality of electronic components. In any case, the battery 106 powers the electronic components present in the PCB 100.

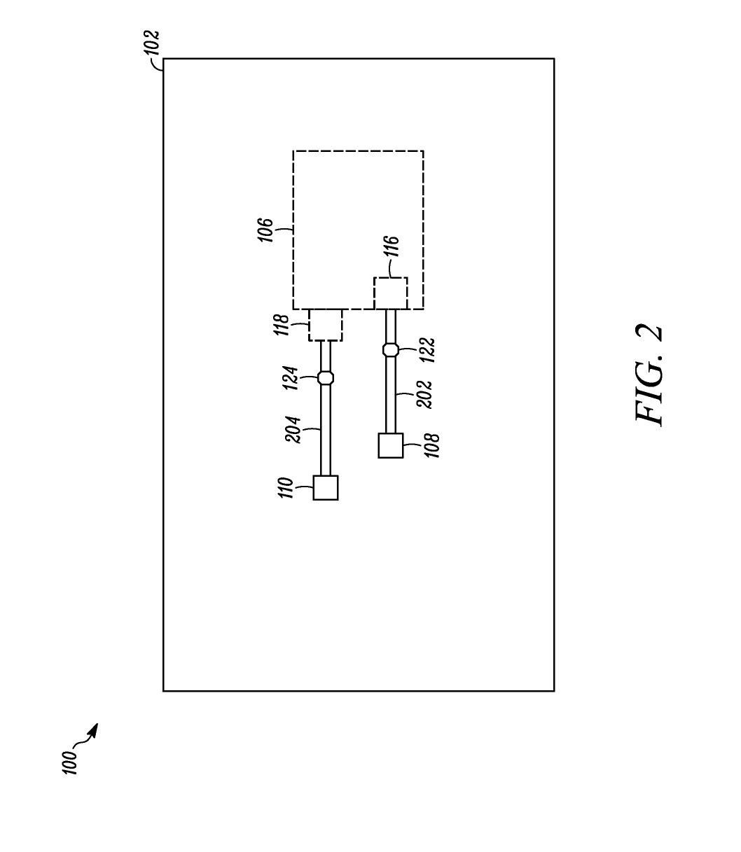

FIG. 2 is a top view of the PCB 100, in accordance with an embodiment of the present invention. As shown in FIG. 2, the top view of the PCB 100 includes a first copper trace 202 and a second copper trace 204, in addition to the first outer pad 108, and the second outer pad 110. The first copper trace 202 electrically connects the first outer pad 108 to the first battery contact via 122 on the outer core layer 102 so that a cathode is provided. The second copper trace 204 electrically connects the second outer pad 110 to the second battery contact via 124 on the outer core layer 102 so that an anode is provided. In one embodiment, the copper trace is electrically conductive metallic copper having a width of approximately 0.25 mm.

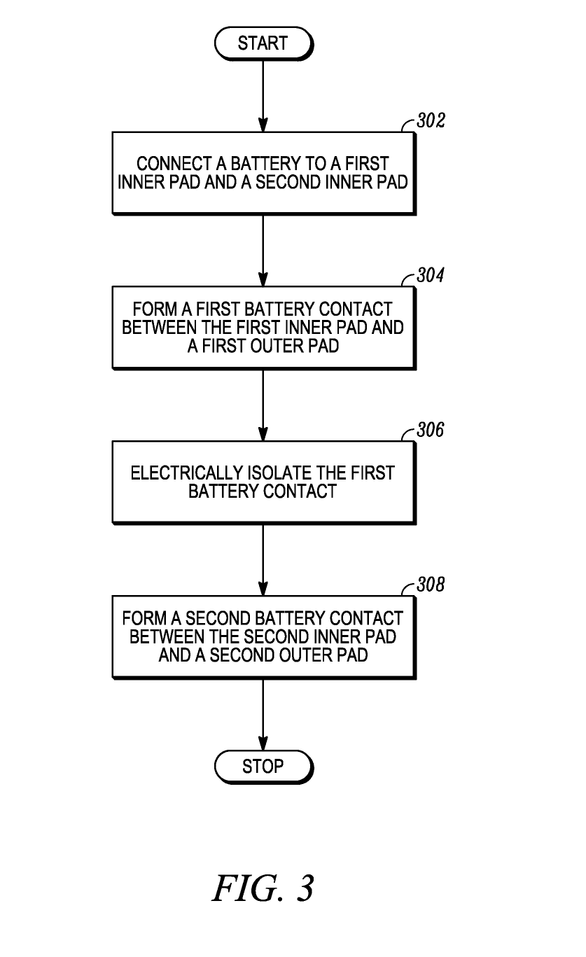

FIG. 3 is a flowchart illustrating a method for imbedding a battery in a PCB, in accordance with an embodiment of the present invention. At step 302, the battery is connected to a first inner pad and a second inner pad on an inner core layer of the PCB. The step of connecting the battery to the first inner pad and the second outer pad includes connecting a first battery contact pad to the first inner pad and connecting a second battery contact pad to the second inner pad. In one embodiment, connecting is performed by using a conductive medium such as conductive epoxy, solder, and the like. In an embodiment, the conductive medium is a Kwik-Stik™ silver colloid, as mentioned above.

In one embodiment, the plurality of core layers, one or more prepreg layers present in the PCB, and the battery imbedded in the PCB are laminated together by using a press lamination process. In one embodiment, the lamination process is a FR4 press process. As such, the FR4 press process may be performed for approximately an hour at 181° C. Alternatively, the FR4 press process may be performed for approximately 40-45 minutes at approximately 181° C. In other alternatives, the FR4 press process may be carried out at temperatures ranging from approximately 150° C. to approximately 230° C. depending on the substrate used in the plurality of core layers. In any case, as used above, approximately is defined as “close to” as understood by one of ordinary skill in the art. For example, in the above one embodiment, the term is defined to be within one hour and within 181° C.

Continuing with FIG. 3, at step 304, a first battery contact is formed between a first outer pad present on an outer core layer and the first inner pad. A first battery contact via is drilled to form the first battery contact. In one embodiment, the first battery contact via is made electrically conducting by plating the first battery contact via with copper, although other elements may be used, e.g. silver, and reference to copper is not meant to be limiting on an embodiment of the present invention. In an embodiment, a plurality of holes are also drilled and plated with copper. The copper may be plated by using electroless plating and may be followed by electrolytic plating.

At step 306, the first battery contact is electrically isolated. In one embodiment, electrically isolating the first battery contact includes selectively etching a conductive layer around the first battery contact. Electrical isolation of the first battery contact is carried out to isolate the first battery contact via from the plurality of holes on the PCB.

At step 308, a second battery contact is formed between a second outer pad, present on the outer core layer, and the second inner pad. A second battery contact via is drilled to form the second battery contact. In one embodiment, the second battery contact via is made electrically conducting by covering the second battery contact via with copper, although other elements may be used, e.g. silver, and reference to copper is not meant to be limiting on an embodiment of the present invention. In one embodiment, prior to covering the second battery contact via, a plating mask is applied on the top and bottom portions of the first battery contact. Covering the second battery contact via with copper may be performed by electroless plating the second battery contact via with copper. After electroless plating, the plating mask is removed and re-applied on the top and bottom portions of the first battery contact. The second battery contact via is then electroplated with copper and the plating mask is removed from the top and bottom portions of the first battery contact. The plating mask is applied to prevent copper deposition on the first battery contact during electroless plating and the electroplating of the second battery contact via. Examples of plating mask include, but are not limited to, a Kapton tape and a photoimageable film.

The method of FIG. 3 may be described with reference to FIGS. 1 and 2. As such, in one embodiment, in the PCB 100, the battery 106 is integrated on the inner core layer 104 by connecting the first battery contact pad 112 to the first inner pad 116 and connecting the second battery contact pad 114 to the second inner pad 118 using the conductive medium 120. The outer core layer 102, the prepreg layer 126, and the inner core layer 104 with the battery 106 are laminated together by using a press lamination process. The first battery contact via 122 is drilled and then plated with copper by using electroless and electrolytic plating. The first battery contact via 122 is electrically isolated by selectively etching a conducting layer from the top of the first battery contact via 122. The second battery contact via 124 is drilled and then covered with copper. A plating mask is applied on the top and bottom portions of the first battery contact via 122 before covering the second battery contact via 124 with copper. The second battery contact via 124 is electroless plated with copper. After electroless plating, the plating mask is removed and again applied on the top and bottom portions of the first battery contact via 122. The second battery contact via 124 is then electroplated with copper, and the plating mask is removed from the top and bottom portions of the first battery contact via 122 after electroplating.

After the battery 106 is imbedded in the PCB 100, a circuit pattern is imaged on the PCB 100, followed by pattern plating, etching, and other existing fabrication processes, to process the PCB 100.

In an embodiment of the present invention, the battery to be imbedded in the PCB is a rechargeable battery, e.g. battery 106. While embedding the rechargeable battery, the first battery contact via and the second battery contact via can be drilled and plated simultaneously. The battery may discharge because of simultaneous plating of the first battery contact via and the second battery contact via. However, the battery can be recharged after the battery has been imbedded in the PCB.

Therefore, as described above, the present invention provides a new PCB and a method for imbedding a battery in a PCB. Since the battery is embedded in the PCB, the electronic device using the PCB does not require a separate battery to power the electronic device. Also, no separate contacts and solder are required for connecting the electronic components to the battery because of the presence of pads on the outer core layer.

It is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

In the foregoing specification, the present invention and its benefits and advantages have been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The present invention is defined solely by the appended claims including any amendments made during the pendency of this application and all equivalents of those claims as issued.

We claim:

1. A method for imbedding a battery in a printed circuit board, the method comprising:
connecting the battery to a first inner pad and a second inner pad, wherein the first inner pad and the second inner pad are present on an inner core layer of a plurality of core layers of the printed circuit board;
forming a first battery contact between the first inner pad and a first outer pad, wherein the first outer pad is present on an outer core layer;
electrically isolating the first battery contact; and
forming a second battery contact between the second inner pad and a second outer pad, wherein the second outer pad is present on the outer core layer,
wherein the first battery contact provides an electrical connection between the first inner pad and the first outer pad and the second battery contact provides an electrical connection between the second inner pad and the second outer pad.

2. The method of claim 1 further comprising coating each of the plurality of core layers with a black oxide coating before connecting the battery to the first inner pad and the second inner pad.

3. The method of claim 1, wherein connecting the battery to the first inner pad and the second inner pad comprises connecting a first battery contact pad with the first inner pad and a second battery contact pad with the second inner pad using a conductive medium.

4. The method of claim 1 further comprising:
inserting one or more prepreg layers between the plurality of core layers; and
laminating the plurality of core layers and the one or more prepreg layers.

5. The method of claim 4, wherein laminating the plurality of core layers and the one or more prepreg layers is performed at a temperature ranging from 150° C. to 230° C.

6. The method of claim 1 further comprising:
creating a plurality of holes on the printed circuit board; and
plating each of the plurality of holes with copper using electroless and electrolytic plating.

7. The method of claim 1, wherein forming the first battery contact comprises:
creating a first battery contact via on the printed circuit board; and
plating the first battery contact via with copper using electroless and electrolytic plating.

8. The method of claim 1, wherein electrically isolating the first battery contact comprises selectively etching a conducting layer from the first battery contact.

9. The method of claim 1, wherein forming the second battery contact comprises:
creating a second battery contact via on the printed circuit board;
applying a plating mask on both surfaces of the first battery contact; and
covering the second battery contact via with copper.

10. The method of claim 9, wherein covering the second battery contact via with copper comprises:
coating the second battery contact via with copper using electroless plating;
removing the plating mask applied on both surfaces of the first battery contact;
reapplying the plating mask on both surfaces of the first battery contact;
electroplating the second battery contact via with copper; and
removing the plating mask applied on both surfaces of the first battery contact.

11. A method for imbedding a battery having a first battery contact pad and a second battery contact pad on a printed circuit board, the method comprising:
connecting the first battery contact pad with a first inner pad and the second battery contact pad with a second inner pad using a conductive medium, wherein the first inner pad and the second inner pad are present on an inner core layer of a plurality of core layers of the printed circuit board;
creating a first battery contact via between the first inner pad and a first outer pad, wherein the first outer pad is present on an outer core layer;
plating the first battery contact via with copper using electroless and electrolytic plating;
electrically isolating the first battery contact via;
creating a second battery contact via between the second inner pad and a second outer pad, wherein the second outer pad is present on the outer core layer;
applying plating mask on the first battery contact via; and
covering the second battery contact via with copper.

12. The method of claim 11 further comprising:
inserting one or more prepreg layers between the plurality of core layers; and
laminating the plurality of core layers and the one or more prepreg layers.

13. The method of claim 12, wherein laminating the plurality of core layers and one or more prepreg layers is performed at a temperature ranging from 150° C. to 230° C.

14. The method of claim 11 further comprising:
creating a plurality of holes on the printed circuit board; and
plating the plurality of holes with copper using electroless and electrolytic plating.

15. The method of claim 11, wherein electrically isolating the first battery contact via comprises selectively etching a conducting layer from the first battery contact via.

16. The method of claim 11, wherein covering the second battery contact via with copper comprises:
coating the second battery contact via with copper using electroless plating;
removing the plating mask from the first battery contact via;
reapplying the plating mask on the first battery contact via;
electroplating the second battery contact via with copper; and
removing the plating mask from the first battery contact via.

17. A printed circuit board comprising:
a plurality of core layers;
a battery imbedded between two of the plurality of core layers, wherein the battery has a first battery contact pad and a second battery contact pad;
a first outer pad connected to the first battery contact pad, wherein the first outer pad is present on an outer core layer of the printed circuit board; and
a second outer pad connected to the second battery contact pad, wherein the second outer pad is present on the outer core layer of the printed circuit board.

18. The printed circuit board of claim 17 further comprising:
a first battery contact via for providing an electrical connection between the first outer pad and a first inner pad, wherein the first inner pad is present on an inner core layer of the plurality of core layers; and
a second battery contact via for providing an electrical connection between the second outer pad and a second inner pad, wherein the second inner pad is present on the inner core layer.

19. The printed circuit board of claim 17 further comprising a plurality of holes electrically connecting a plurality of electronic components integrated on the printed circuit board.

20. The printed circuit board of claim 17, wherein the battery is a rechargeable battery.
